(19) United States
(12) Patent Application Publication
(10) Pub. No.: US 2016/0079340 A1
(43) Pub. Date: Mar. 17, 2016

(54) SEMICONDUCTOR DEVICE AND METHOD FOR MANUFACTURING THE SAME

(71) Applicant: Kabushiki Kaisha Toshiba, Minato-ku (JP)

(72) Inventors: Tomohiro Yamada, Yokkaichi (JP); Haruhiko Koyama, Yokkaichi (JP)

(73) Assignee: Kabushiki Kaisha Toshiba, Minato-ku (JP)

(21) Appl. No.: 14/812,033

(22) Filed: Jul. 29, 2015

(30) Foreign Application Priority Data
Sep. 15, 2014 (JP) 2014-187151

(51) Int. Cl. H01L 49/02; H01L 29/06; H01L 21/3205; H01L 21/3105; H01L 21/768; H01L 23/522; H01L 21/762

(52) U.S. Cl. CPC H01L 28/10; H01L 23/5226; H01L 29/0649; H01L 21/76224; H01L 21/31051; H01L 21/76877; H01L 21/32051

(57) ABSTRACT

A semiconductor device according to one embodiment includes a semiconductor substrate, an insulating member provided in a first region on the semiconductor substrate, an insulating film provided in a second region not provided with the insulating member on the semiconductor substrate, a conductive member provided on the insulating member and on the insulating film, and a first and a second vias connected to the conductive member. An upper surface of the insulating film is lower than an upper surface of the insulating member. An upper part of the conductive member is provided in both the first region and the second region, and a lower part is provided in the second region and not provided in the first region. The conductive member has at least one portion located on the first region between the first via and the second via.

### CROSS-REFERENCE TO RELATED APPLICATIONS

This application is based upon and claims the benefit of priority from Japanese Patent Application No.2014-187151, filed on Sep. 15, 2014; the entire contents of which are incorporated herein by reference.

### FIELD

Embodiments described herein relate generally to a semiconductor device and a method for manufacturing the same.

### BACKGROUND

In a semiconductor device, an upper surface of a device isolation insulator provided in an STI (shallow trench isolation) region is located at a higher position than an upper surface of a silicon oxide film provided in an active region. Thus, a polysilicon film formed in the STI region is thinner than a polysilicon film formed in the active region. Accordingly, in the case of providing a resistance member made of polysilicon on a silicon substrate, it is desirable that the resistance member be placed in the STI region in order to increase the sheet resistance.

### BRIEF DESCRIPTION OF THE DRAWINGS

FIG. 1 is a plan view illustrating a semiconductor device according to a first embodiment;

FIGS. 2A to 3B are sectional views illustrating the semiconductor device according to the first embodiment;

FIGS. 4A to 4C, 5A, and 5B are sectional views illustrating a method for manufacturing a semiconductor device according to the first embodiment;

FIG. 6A is a plan view illustrating a semiconductor device according to a comparative example, FIG. 6B is a sectional view illustrating it;

FIG. 7 is a plan view illustrating a semiconductor device according to a second embodiment; and

FIGS. 8A to 9B are sectional views illustrating the semiconductor device according to the second embodiment.

### DETAILED DESCRIPTION

A semiconductor device according to one embodiment includes a semiconductor substrate, an insulating member provided in a first region on the semiconductor substrate, an insulating film provided in a second region not provided with the insulating member on the semiconductor substrate, a conductive member provided on the insulating member and on the insulating film, and a first and a second vias connected to the conductive member. An upper surface of the insulating film is lower than an upper surface of the insulating member. An upper part of the conductive member is provided in both the first region and the second region, and a lower part of the conductive member is provided in the second region and not provided in the first region. The conductive member has at least one portion on the first region. The one portion is located between a first portion of the conductive member connected with the first via and a second portion of the conductive member connected with the second via.

A method for manufacturing a semiconductor device according to one embodiment includes forming an insulating film, a first conductive film, and a stopper film on a semiconductor substrate. The method includes forming a trench in a first region. The trench penetrates through the stopper film, the first conductive film, and insulating film into the semiconductor substrate. The method includes forming a device isolation insulator in the trench. The method includes performing planarization processing using the stopper film as a stopper. The method includes removing the stopper film. The method includes forming a second conductive film in contact with the first conductive film. The method includes forming a conductive member including the first conductive film and the second conductive film in the first region and a second region provided with the insulating film on the semiconductor substrate by selectively removing the second conductive film and the first conductive film. The method includes forming a first and a second vias connected to the conductive member. The first and the second vias are formed at positions on the conductive member so that the conductive member has at least one portion on the first region. The one portion is located between a first portion of the conductive member connected with the first via and a second portion of the conductive member connected with the second via.

### First Embodiment

Embodiments of the invention will now be described with reference to the drawings.

First, a first embodiment is described.

The semiconductor device according to the embodiment is e.g. a multilayer semiconductor memory device including a resistance element in the peripheral circuit section.

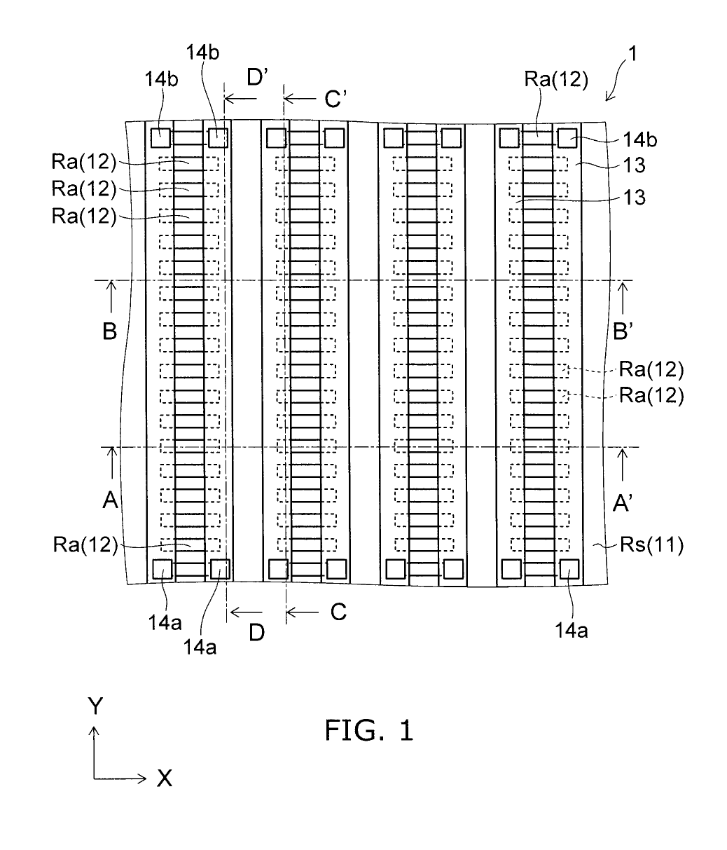

FIG. 1 is a plan view illustrating a semiconductor device according to the embodiment.

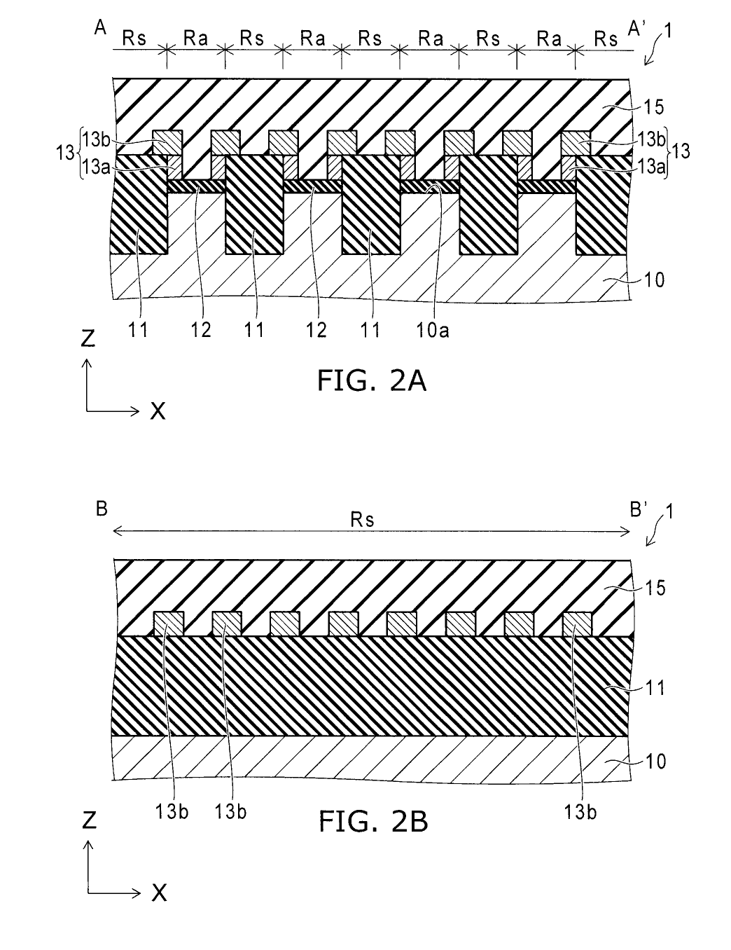

FIGS. 2A and 2B are sectional views illustrating the semiconductor device according to the embodiment. FIG. 2A is a sectional view taken along line A-A′ shown in FIG. 1. FIG. 2B is a sectional view taken along line B-B′ shown in FIG. 1.

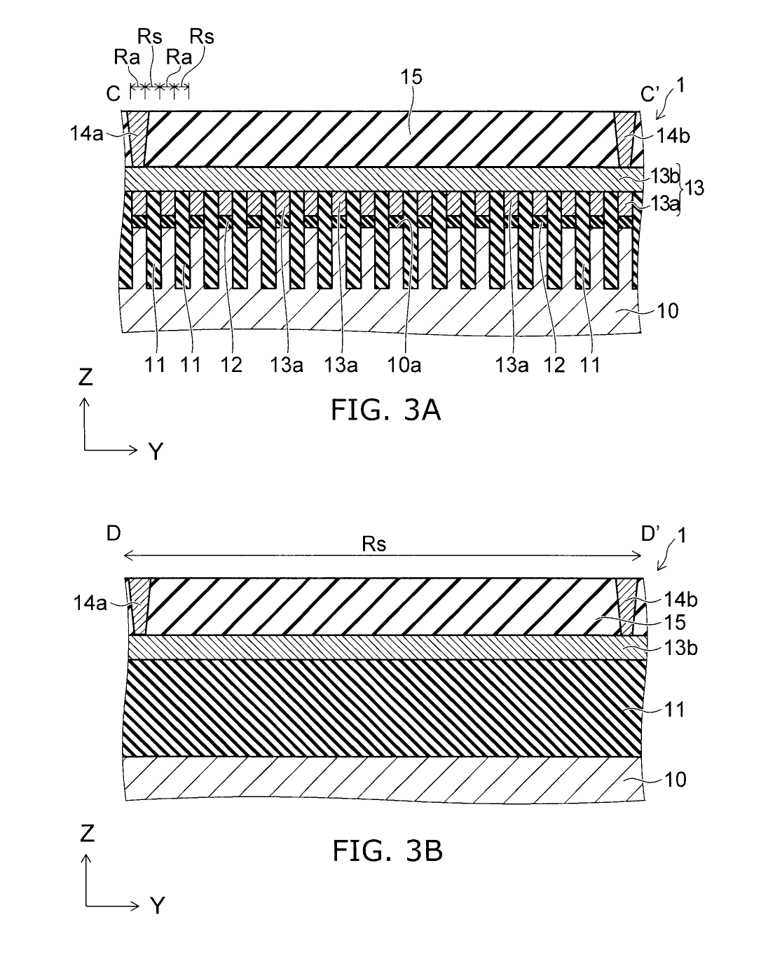

FIGS. 3A and 3B are sectional views illustrating the semiconductor device according to the embodiment. FIG. 3A is a sectional view taken along line C-C′ shown in FIG. 1. FIG. 3B is a sectional view taken along line D-D′ shown in FIG. 1.

The region shown in FIG. 1 is e.g. a region in which a resistance element is formed in the peripheral circuit section of a multilayer semiconductor memory device.

As shown in FIGS. 1, 2A, 2B, 3A, and 3B, the semiconductor device 1 according to the embodiment includes a silicon substrate 10. In the following, for convenience of description, an XYZ orthogonal coordinate system is adopted in the specification. Two directions parallel to the upper surface 10a of the silicon substrate 10 and orthogonal to each other are referred to as “X-direction” and “Y-direction”. The direction perpendicular to the upper surface 10a of the silicon substrate 10 is referred to as “Z-direction”.

An insulator region Rs and a semiconductor region Ra are specified on the silicon substrate 10. As viewed in the Z-direction, the insulator region Rs is shaped like a lattice extending in the X-direction and the Y-direction. The semiconductor region Ra is shaped like a rectangle with the longitudinal direction being the X-direction. A plurality of semiconductor regions Ra are arranged in a matrix along the X-direction and the Y-direction. In the region (not shown) in which an active element is provided in the semiconductor device 1, the semiconductor region Ra is a region used as an active region, and the insulator region Rs is a region used as an STI region.

In the insulator region Rs, a device isolation insulator 11 as an insulating member is provided on the silicon substrate 10. The device isolation insulator 11 is formed from silicon oxide. In the semiconductor region Ra, a silicon oxide film 12 as an insulating film is provided on the silicon substrate 10. The upper surface of the device isolation insulator 11 is located above the upper surface of the silicon oxide film 12. The lower surface of the device isolation insulator 11 is located below the upper surface 10a of the silicon substrate 10.

A plurality of polysilicon films 13 are provided as conductive members above the silicon substrate 10 and the device isolation insulator 11. The polysilicon film 13 is formed from polycrystalline silicon containing impurity. Each polysilicon film 13 is shaped like a line extending in the Y-direction. Each polysilicon film 13 is placed so as to pass through one X-direction end part of a plurality of semiconductor regions Ra. Thus, as shown in FIG. 3A, one side portion in the width direction of the polysilicon film 13 alternately passes through the insulator region Rs and the semiconductor region Ra. Furthermore, as shown in FIG. 3B, the other side portion in the width direction of the polysilicon film 13 passes through only the insulator region Rs. The width, i.e., Y-direction length, of the semiconductor region Ra is shorter than the width, i.e., X-direction length, of the polysilicon film 13.

The polysilicon film 13 includes a lower layer 13a and an upper layer 13b. In the Z-direction, the position of the interface between the lower layer 13a and the upper layer 13b is nearly equal to the position of the upper surface of the device isolation insulator 11. Accordingly, the lower layer 13a is sandwiched between the device isolation insulators 11. Thus, the lower layer 13a is placed in only the semiconductor region Ra. On the other hand, the upper layer 13b is mounted on the device isolation insulator 11 and on the lower layer 13a. Thus, the upper layer 13b is placed in both the semiconductor region Ra and the insulator region Rs.

Two vias 14a and 14b are provided directly above each polysilicon film 13 and connected to the polysilicon film 13. The via 14a and the via 14b are connected to positions spaced in the Y-direction on one polysilicon film 13. Thus, the portion of the polysilicon film 13 located between the via 14a and the via 14b functions as a resistance element. The portion of the polysilicon film 13 located between the via 14a and the via 14b traverses the insulator region Rs a plurality of times. An interlayer insulating film 15 is provided on the silicon substrate 10 so as to embed the device isolation insulator 11, the silicon oxide film 12, the polysilicon film 13, and the vias 14a and 14b. For convenience of illustration, the interlayer insulating film 15 is not shown in FIG. 1.

Next, a method for manufacturing a semiconductor device according to the embodiment is described.

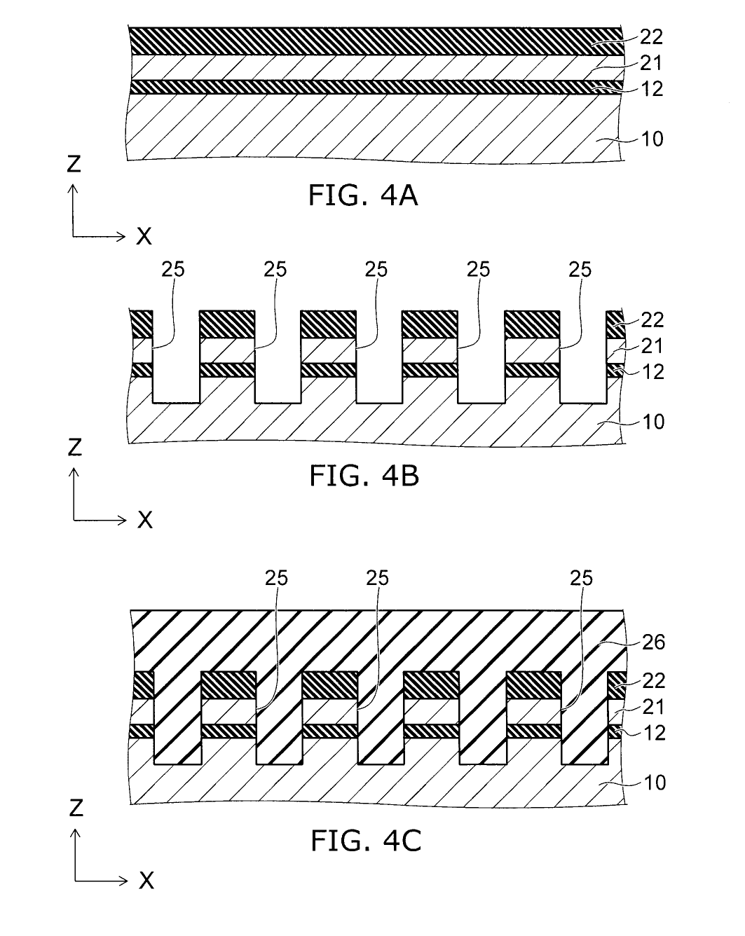

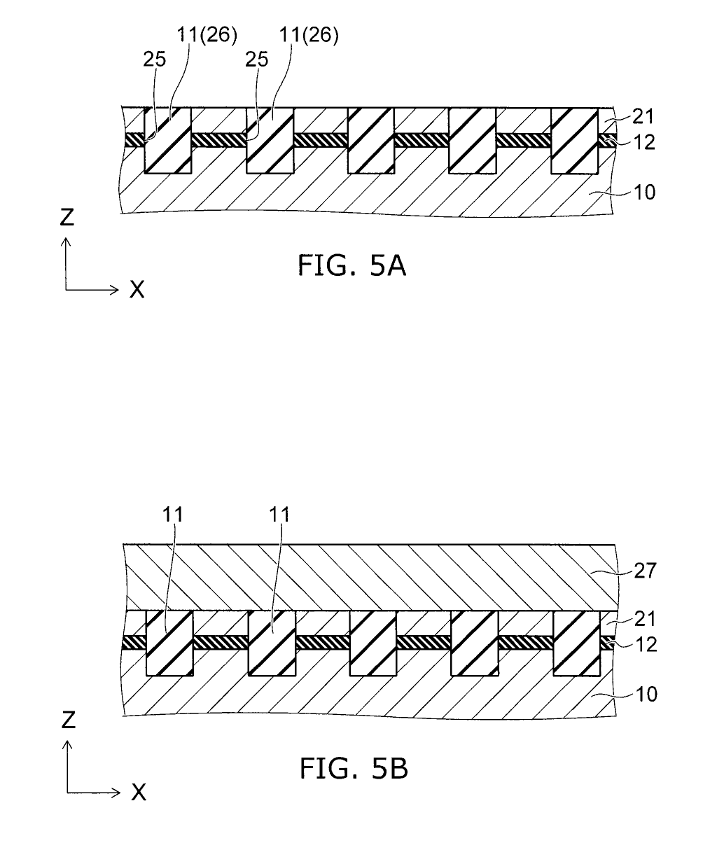

FIGS. 4A to 4C, 5A, and 5B are sectional views illustrating a method for manufacturing a semiconductor device according to the embodiment.

The region shown in FIGS. 4A to 4C, 5A, and 5B corresponds to the cross section taken along line A-A′ shown in FIG. 1.

First, as shown in FIG. 4A, a silicon oxide film 12 as an insulating film, a polysilicon film 21 as a first conductive film, and a silicon nitride film 22 as a stopper film are formed in this order on a silicon substrate 10 as a semiconductor substrate.

Next, as shown in FIG. 4B, a photoresist mask film (not shown) is formed so as to cover the semiconductor region Ra by lithography technique. Next, this photoresist mask film is used as a mask to perform RIE (reactive ion etching). Thus, the silicon nitride film 22, the polysilicon film 21, the silicon oxide film 12, and an upper portion of the silicon substrate 10 are selectively removed. Accordingly, a trench 25 is formed. The trench 25 penetrates through the silicon nitride film 22, the polysilicon film 21, and the silicon oxide film 12 into the silicon substrate 10. As viewed from above, i.e., the Z-direction, the trench 25 is shaped like a lattice. Next, the photoresist mask film is removed.

Next, as shown in FIG. 4C, a silicon oxide film 26 is formed on the entire surface by e.g. CVD (chemical vapor deposition) technique. The silicon oxide film 26 is embedded also in the trench 25.

Next, as shown in FIG. 5A, the silicon nitride film 22 is used as a stopper film to perform planarization processing such as CMP (chemical mechanical polishing). Thus, the portion of the silicon oxide film 26 formed on the silicon nitride film 22 is removed. Next, the silicon nitride film 22 is removed by wet etching with hot phosphoric acid. Thus, the upper surface of the polysilicon film 21 is exposed. Next, the portion of the silicon oxide film 26 projected from the upper surface of the polysilicon film 21 is removed by wet etching with hydrofluoric acid. Thus, the upper surface of the polysilicon film 21 and the upper surface of the silicon oxide film 26 are turned to a nearly flat continuous surface. By the foregoing process, the silicon oxide film 26 is left only in the trench 25 and constitutes a device isolation insulator 11.

Next, as shown in FIG. 5B, a polysilicon film 27 as a second conductive film is formed on the entire surface. The polysilicon film 27 is in contact with the polysilicon film 21.

Next, as shown in FIG. 2A, a photoresist mask film (not shown) having a line-and-space pattern extending in the Y-direction is formed. Next, this photoresist mask film is used as a mask to perform RIE. Thus, the polysilicon film 27 and the polysilicon film 21 are processed into a line-and-space pattern extending in the Y-direction. Accordingly, a polysilicon film 13 is formed. At this time, the polysilicon film 21 constitutes a lower layer 13a, and the polysilicon film 27 constitutes an upper layer 13b. Next, the photoresist mask film is removed.

Next, an interlayer insulating film 15 is formed by depositing e.g. silicon oxide on the entire surface. Next, vias 14a and 14b are formed in the interlayer insulating film 15. Thus, the semiconductor device 1 according to the embodiment is manufactured.

Next, the effect of the embodiment is described.

In the semiconductor device 1 according to the embodiment, the lattice-shaped insulator region Rs and the matrix-shaped semiconductor region Ra are intertwined. The polysilicon film 13 is placed so as pass through both the insulator region Rs and the semiconductor region Ra.

Thus, the insulator region Rs and the semiconductor region Ra are intertwined. Accordingly, in the step shown in FIG. 5A, the entirety can be uniformly polished by CMP. Thus, the semiconductor device 1 according to the embodiment is easy to manufacture.

Furthermore, the polysilicon film 13 is placed in both the insulator region Rs and the semiconductor region Ra. Thus, all the polysilicon films 13 are suitable for resistance elements. Accordingly, there is no need to provide dummy resistance elements. Thus, no dead space occurs in the formation region of resistance elements. This can downsize the semiconductor device.

Furthermore, in the polysilicon film 13, the upper layer 13b extends continuously along the longitudinal direction (Y-direction) of the polysilicon film 13 and constitutes a current path. However, the lower layer 13a is divided in the Y-direction and has little contribution as a current path. That is, the effective current path in the polysilicon film 13 is only the upper layer 13b. Thus, the sheet resistance of the polysilicon film 13 placed in both the insulator region Rs and the semiconductor region Ra is comparable to the sheet resistance of the polysilicon film 13 consisting only of the upper layer 13b placed in the insulator region Rs. Accordingly, a large resistance value can be obtained with a small area by realizing a resistance element from the polysilicon film 13. As a result, the semiconductor device can be downsized.

### Comparative Example

Next, a comparative example is described.

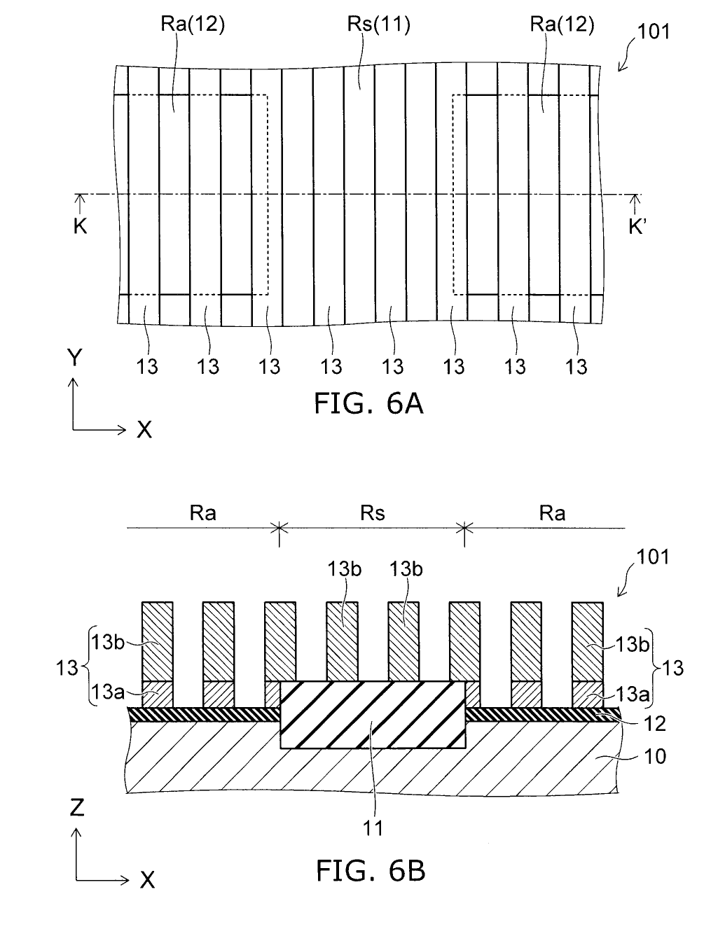

FIG. 6A is a plan view illustrating a semiconductor device according to the comparative example. FIG. 6B is a sectional view.

FIG. 6B shows a cross section taken along line K-K′ shown in FIG. 6A.

As shown in FIGS. 6A and 6B, a relatively large semiconductor region Ra and an insulator region Rs are specified in the semiconductor device 101 according to the comparative example. Some of the polysilicon films 13 are provided in both the semiconductor region Ra and the insulator region Rs. The other polysilicon films 13 are provided only in the insulator region Rs.

In the semiconductor device 101, in the polysilicon film 13 passing through the semiconductor region Ra, the lower layer 13a extends continuously over a certain length such as a length longer than the width of the polysilicon film 13. Thus, the lower layer 13a also forms a current path in addition to the upper layer 13b. Accordingly, the polysilicon film 13 has low sheet resistance. Thus, in the semiconductor device 101, among the polysilicon films 13, only the polysilicon films 13 not passing through the semiconductor region Ra but placed in the insulator region Rs over the entire length are suitable for resistance elements. The polysilicon films 13 passing through the semiconductor region Ra are unsuitable for resistance elements. In the example shown in FIGS. 6A and 6B, only two central polysilicon films 13 provided in the insulator region Rs are used as resistance elements. Left and right polysilicon films 13, three for each, are dummy resistance elements. Thus, the polysilicon films 13 passing through the semiconductor region Ra are dummy resistance elements. The region provided with the dummy resistance elements is a dead space. This hampers downsizing of the semiconductor device.

It may be considered to eliminate dummy resistance elements by specifying only the insulator region Rs without specifying the semiconductor region Ra in the formation region of resistance elements. However, in this case, dishing occurs in the CMP process. That is, silicon oxide is polished more easily than silicon nitride. Thus, for instance, when performing CMP in the step shown in FIG. 5A, the upper surface of the silicon oxide film 26 is made lower than the upper surface of the silicon nitride film 22. This decreases the flatness of the upper surface. This decrease of flatness adversely affects the subsequent process. Such specification of the insulator region Rs is normally prohibited by the manufacturing rule.

### Second Embodiment

Next, a second embodiment is described.

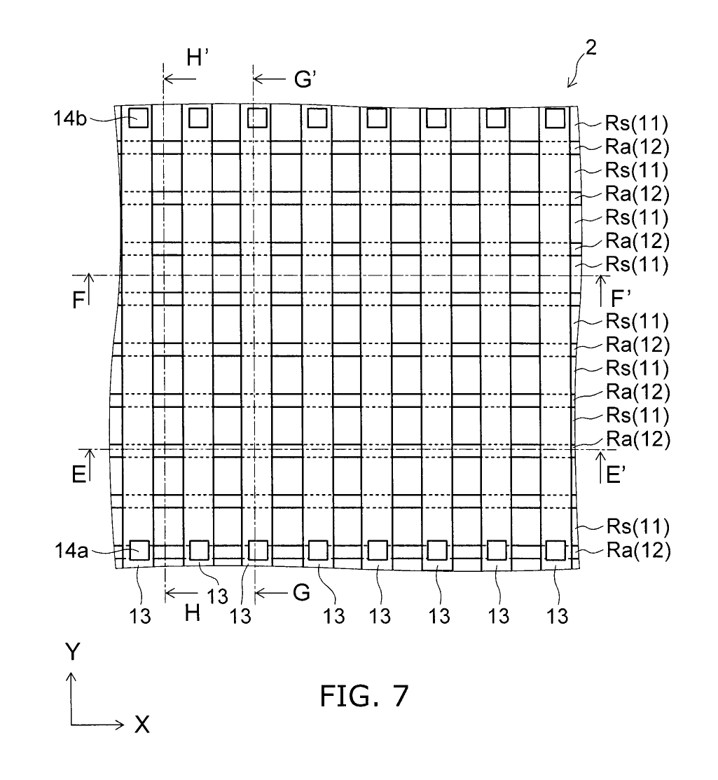

FIG. 7 is a plan view illustrating a semiconductor device according to the embodiment.

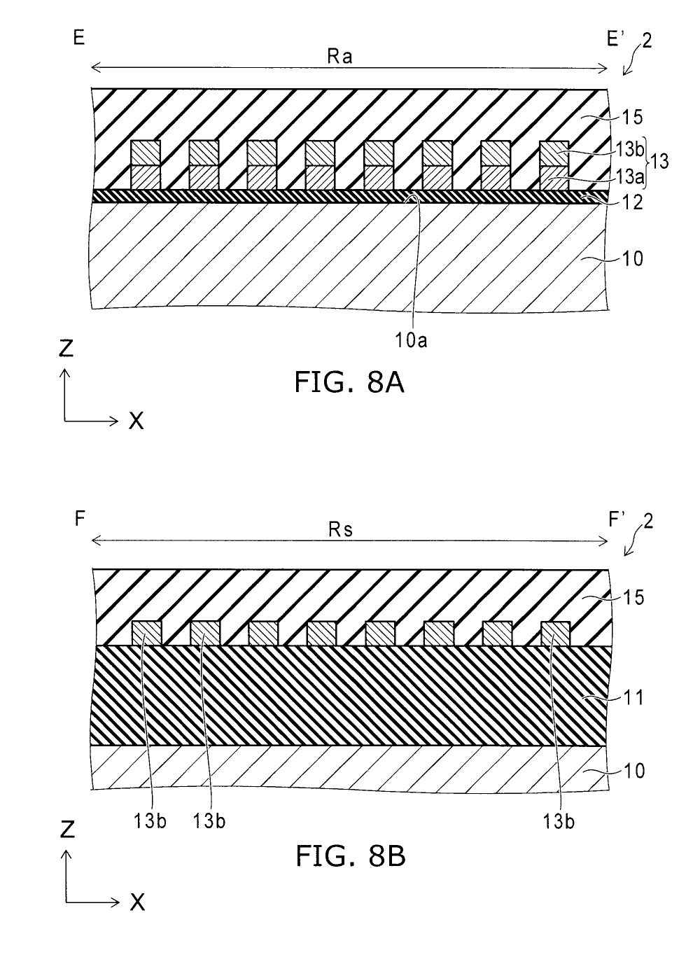

FIGS. 8A and 8B are sectional views illustrating the semiconductor device according to the embodiment. FIG. 8A is a sectional view taken along line E-E′ shown in FIG. 7. FIG. 8B is a sectional view taken along line F-F′ shown in FIG. 7.

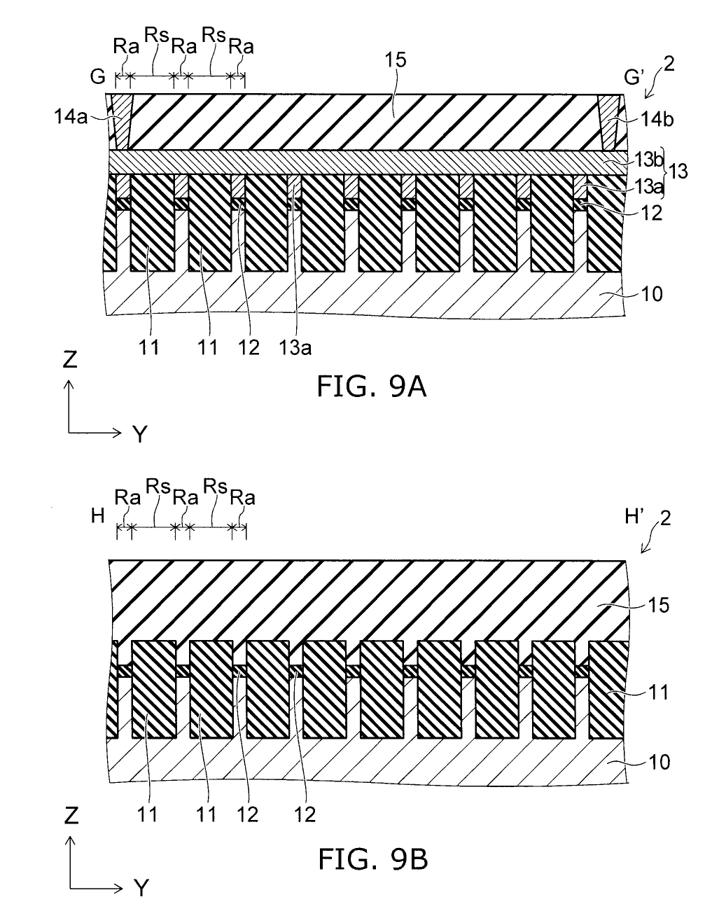

FIGS. 9A and 9B are sectional views illustrating the semiconductor device according to the embodiment. FIG. 9A is a sectional view taken along line G-G′ shown in FIG. 7. FIG. 9B is a sectional view taken along line H-H′ shown in FIG. 7.

As shown in FIGS. 7, 8A, 8B, 9A, and 9B, the semiconductor device 2 according to the embodiment is different from the semiconductor device 1 (see FIG. 1, etc.) according to the above first embodiment in that the insulator region Rs and the semiconductor region Ra are both shaped like a line extending in the X-direction. The polysilicon film 13 is shaped like a line extending in the Y-direction as in the first embodiment. Thus, as viewed in the Z-direction, the semiconductor regions Ra and the polysilicon films 13 form a lattice. The polysilicon film 13 alternately traverses the insulator region Rs and the semiconductor region Ra as going from the portion connected with the via 14a toward the portion connected with the via 14b. Furthermore, for instance, the width of the semiconductor region Ra is shorter than the width of the polysilicon film 13.

According to the embodiment, in the step shown in FIG. 4B, the photoresist mask film (not shown) for forming the trench 25 can be formed in a line-and-space pattern. Thus, lithography is easier than in the above first embodiment.

The configuration, manufacturing method, and effect of the embodiment other than the foregoing are similar to those of the above first embodiment. That is, also in the embodiment, the insulator region Rs and the semiconductor region Ra are intertwined as in the first embodiment. This provides good flatness achieved by CMP. Furthermore, the lower layer 13a in the polysilicon film 13 is finely divided along the Y-direction. This can impart high resistance to the polysilicon film 13. Thus, all the polysilicon films 13 can be used as resistance elements. This provides good area efficiency.

The embodiments described above can realize a semiconductor device easy to manufacture and capable of downsizing, and a method for manufacturing the same.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a semiconductor substrate;
an insulating member provided in a first region on the semiconductor substrate;
an insulating film provided in a second region not provided with the insulating member on the semiconductor substrate, an upper surface of the insulating film being lower than an upper surface of the insulating member;
a conductive member provided on the insulating member and on the insulating film; and
a first and a second vias connected to the conductive member,
an upper part of the conductive member being provided in both the first region and the second region, and a lower part of the conductive member being provided in the second region and not provided in the first region, and
the conductive member having at least one portion on the first region, the one portion being located between a first portion of the conductive member connected with the first via and a second portion of the conductive member connected with the second via.

2. The device according to claim 1, wherein the insulating member is shaped like a lattice as viewed from above.

3. The device according to claim 1, wherein the insulating member is shaped like a line as viewed from above.

4. The device according to claim 1, wherein the conductive member has a plurality of portions on the first region, the plurality of portions are located between the first portion and the second portion.

5. The device according to claim 1, wherein a resistance element portion of the conductive member connected between the first portion and the second portion is shaped like a line.

6. The device according to claim 5, wherein length of the second region in extending direction of the resistance element portion is shorter than width of the resistance element portion.

7. The device according to claim 1, wherein the semiconductor substrate is a silicon substrate, the insulating member and the insulating film are made of silicon oxide, and the conductive member is made of silicon containing impurity.

8. A method for manufacturing a semiconductor device, comprising:
forming an insulating film, a first conductive film, and a stopper film on a semiconductor substrate;
forming a trench in a first region, the trench penetrating through the stopper film, the first conductive film, and insulating film into the semiconductor substrate;
forming a device isolation insulator in the trench;
performing planarization processing using the stopper film as a stopper;
removing the stopper film;
forming a second conductive film in contact with the first conductive film;
forming a conductive member including the first conductive film and the second conductive film in the first region and a second region provided with the insulating film on the semiconductor substrate by selectively removing the second conductive film and the first conductive film; and
forming a first and a second vias connected to the conductive member,
the first and the second vias being formed at positions on the conductive member so that the conductive member has at least one portion on the first region, the one portion being located between a first portion of the conductive member connected with the first via and a second portion of the conductive member connected with the second via.

9. The method according to claim 8, wherein the trench is formed like a lattice as viewed from above.

10. The method according to claim 8, wherein the trench is formed like a line as viewed from above.
